(19) United States
(12) Patent Application Publication
(10) Pub. No.: US 2007/0275498 A1
(43) Pub. Date: Nov. 29, 2007

(54) Enhancing performance in ink-jet printed organic semiconductors

(76) Inventors: Paul Beecher, Cambridge (GB); Alan Colli, Cambridge (GB); Oleksly Rozhin, Cambridge (GB); Peyman Servati, Cambridge (GB); Andrea Fasoli, (US); Andrea C. Ferrari, (US); Andrew Flewitt, (US); John Robertson, (US); William I. Milne, (US)

Correspondence Address: WILMER CUTLER PICKERING HALE AND DORR LLP, 399 PARK AVENUE, NEW YORK, NY, 10022, US

(21) Appl. No.: 11/441,498

(22) Filed: May 26, 2006

(51) Int. Cl. H01L 51/40

(52) U.S. Cl. 438/99

(57) ABSTRACT

Systems and methods are provided to improve the performance of electronic and optoelectronic devices made using organic semiconductor processing technology. An ink-jet device dispenses an organic composite mixture onto a substrate. The mixture includes a semiconducting polymer and nanomaterials dispersed into an organic solvent. The type of solvent used preferably achieves effective dispersion of the polymer and nanomaterials in the solvent to minimize the occurrence of clogging of the ink-jet nozzles. The range of nanomaterials include, but are not limited to, organic and inorganic, single or multi-walled nanotubes, nanowires, nanodots, quantum dots, nanorods, nanocrystals, nanotetrapods, nanotripods, nanobipods, nanoparticles, nanosaws, nanosprings, nanoribbons, any branched nanostructure, and any mixture of these nanoshaped materials. The nanostructures can be aligned on the substrate to improve the carrier mobility in the organic semiconductors.

This patent disclosure contains material that is subject to copyright protection. The copyright owner has no objection to the facsimile reproduction by anyone of the patent document or the patent disclosure as it appears in the U.S. Patent and Trademark Office patent file or records, but otherwise reserves any and all copyright rights.

### 1. FIELD OF THE INVENTION

The present invention relates to polymer-based electronic and optoelectronic devices fabricated by ink-jet printing techniques. More particularly, the present invention relates to using nanomaterials to improve the performance of ink-jet printed devices.

### 2. BACKGROUND OF THE INVENTION

Semiconductor technology has played an important role in the development of electronic circuits over the past several decades. Two examples of semiconductor technology include complementary metal oxide semiconductor (CMOS) processing technology and organic semiconductor processing technology.

CMOS processing technology has been around for many years. In CMOS processing technology, silicon metal oxide semiconductor field-effect transistors (MOSFETs) are used to make electronic circuits.

Organic semiconductor processing technology was developed more recently. In organic semiconductor processing technology, organic materials are used to make electronic and optoelectronic circuits. Polymers, which exhibit semiconducting properties, can be used to fabricate electronic and optoelectronic devices on both rigid and flexible, organic and inorganic, substrates. There is also much interest in using polymers as sensors and photodetectors. Ink-jet printers can be used to manufacture polymer-based devices.

Compared to CMOS processing technology, organic semiconductor processing technology is advantageously cheaper to implement and more suitable to specific applications such as flexible electronics and displays. This is particularly advantageous for large area displays. But circuits created using organic semiconductor processing technology are slower and less durable than circuits created using CMOS processing technology.

Therefore, there is a need in the art to improve the performance of electronic and optoelectronic circuits made using organic semiconductor processing technology.

Accordingly, it is desirable to provide methods and systems that overcome these and other deficiencies of the prior art.

### 3. SUMMARY OF THE INVENTION

In accordance with the present invention, systems and methods are provided to improve the performance of electronic and optoelectronic circuits made using organic semiconductor processing technology.

An ink-jet device disperses a composite mixture onto a substrate. The mixture includes a semiconducting polymer and nanomaterials dispersed into an organic solvent. The type of solvent used preferably achieves effective dispersion of the polymer and nanomaterials in the solvent to minimize the occurrence of clogging of the ink-jet nozzles. The nanomaterials can be nanotubes and/or nanostructures. The nanomaterials can include, but are not limited to, organic and inorganic, single or multi-walled nanotubes, nanowires, nanodots, quantum dots, nanorods, nanocrystals, nanotetrapods, nanotripods, nanobipods, nanoparticles, nanosaws, nanosprings, nanoribbons, any branched nanostructure, any mixture of these nanoshaped materials, and/or any other suitable nanomaterials or combination of nanomaterials. The nanomaterials can aid the alignment of the rod-like organic molecules in the polymers to improve the carrier mobility and conductivity of the organic semiconductors. The nanomaterials can also act as enhancers of light, chemical or biological signal detection and conversion into electrical signals.

According to one or more embodiments of the invention, the invention advantageously improves the carrier mobility and conductivity of transistors, the carrier mobility and data processing speed in radio frequency identification (RFID) tags, the responsitivity of photodetectors, and the detection range of bio and chemical sensors produced using ink-jet manufacturing.

According to one or more embodiments of the invention, a method is provided for improving the performance of an organic semiconductor device produced using an ink-jet, the method comprising the steps of: dispersing a semiconducting polymer in an organic solvent; dispersing a plurality of nanomaterials in the organic solvent; and depositing a mixture comprising the organic solvent, the semiconducting polymer, and the plurality of nanomaterials from the ink-jet onto a substrate.

There has thus been outlined, rather broadly, the more important features of the invention in order that the detailed description thereof that follows may be better understood, and in order that the present contribution to the art may be better appreciated. There are, of course, additional features of the invention that will be described hereinafter and which will form the subject matter of the claims appended hereto.

In this respect, before explaining at least one embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of description and should not be regarded as limiting.

As such, those skilled in the art will appreciate that the conception, upon which this disclosure is based, may readily be utilized as a basis for the designing of other structures, methods and systems for carrying out the purposes of the present invention. It is important, therefore, that the claims be regarded as including such equivalent constructions insofar as they do not depart from the spirit and scope of the present invention.

These together with the other objects of the invention, along with the various features of novelty which characterize the invention, are pointed out with particularity in the claims annexed to and forming a part of this disclosure. For a better understanding of the invention, its operating advantages and the specific objects attained by its uses, reference should be had to the accompanying drawings and descriptive matter in which there are illustrated preferred embodiments of the invention.

### 4. BRIEF DESCRIPTION OF THE DRAWINGS

Various objects, features, and advantages of the present invention can be more fully appreciated with reference to the following detailed description of the invention when considered in connection with the following drawings, in which like reference numerals identify like elements:

FIGS. 1A and 1B are diagrams of a cross-sectional side view of a polymer transistor in accordance with different embodiments of the invention;

FIG. 2 is a diagram of a top view of a polymer transistor in accordance with an embodiment of the invention;

FIG. 3 is a diagram of a cross-sectional side view of a polymer sensor in accordance with an embodiment of the invention;

FIG. 4 is a diagram of a top view of a polymer sensor in accordance with an embodiment of the invention; and

FIGS. 5-7 are flow diagrams of processes for ink-jet printing in accordance with different embodiments of the invention.

### 5. DETAILED DESCRIPTION OF THE PREFERRED EMBODIMENTS

In the following description, numerous specific details are set forth regarding the systems and methods of the present invention and the environment in which such systems and methods may operate, etc., in order to provide a thorough understanding of the present invention. It will be apparent to one skilled in the art, however, that the present invention may be practiced without such specific details, and that certain features, which are well known in the art, are not described in detail in order to avoid complication of the subject matter of the present invention. In addition, it will be understood that the examples provided below are exemplary, and that it is contemplated that there are other systems and methods that are within the scope of the present invention.

In accordance with the present invention, systems and methods are provided to improve the performance of electronic and optoelectronic circuits made using organic semiconductor processing technology. The electronic and optoelectronic circuits can include devices such as, for example, transistors, sensors, light emitting diodes, photovoltaic devices, or any other suitable device or combination of devices.

A semiconductor can be realized using an ink-jet printed composite mixture. A semiconductor, such as a transistor, generally includes a source electrode, a drain electrode, a gate, a substrate on which the electrodes and gate sit, and a dielectric that insulates both the source electrode and the drain electrode from the gate. A channel exists between the source electrode and the drain electrode. When the gate is turned “ON,” current flows between the electrodes via the channel.

In organic semiconductor processing technology, an ink-jet device disperses a suitable composite mixture onto a substrate. The substrate can be an organic substrate or an inorganic substrate. The substrate can include, for example, glass, silicon (including electrode bearing silicon substrates), polyimide, indium tin oxide (ITO), or any other suitable substrate.

The composite mixture includes a semiconducting polymer having structures on a nanometer scale (i.e., nanomaterials) dispersed into an organic solvent. The polymer can be dispersed in a solvent that is the same as, or different from, the solvent in which the nanomaterials are dispersed. In a preferred embodiment, the polymer and the nanomaterials are dispersed in the same solvent to facilitate the formation of a polymer and nanomaterial composite. Dispersion can be accomplished using any suitable process such as, for example, ultrasonication.

The type of solvent used preferably results in effective dispersion of the polymer and nanomaterials in the solvent, thereby minimizing the occurrence of clogging of the ink-jet nozzles. The polymer can be, for example, poly(3-hexylthiophene) (P3HT), dioctylfluorene-bithiophene (F8T2), poly(3,3′″-dialkyl-quaterthiophene) (PQT), pentacene, or any other suitable polymer. The solvent can be, for example, isopropyl alcohol (IPA), dimethylformamide (DMF), toluene, chloroform, xylene, N-methylpyrrolidone (NMP), or any other suitable solvent.

The composite mixture can include any suitable nanomaterials or combination of nanomaterials. The nanomaterials can be nanotubes and/or nanostructures.

In one embodiment, the nanomaterials can be nanotubes. A nanotube is a hollow cylinder having dimensions on the order of a nanometer. The nanotube can be made of carbon or any other suitable material. The composite mixture can include nanotubes of the same material or of different materials.

In another embodiment, the nanomaterials can be nanowires. A nanowire is a wire having dimensions on the order of a nanometer. The nanowires can be made of silicon or any other suitable material. The composite mixture can include nanowires of the same material or of different materials.

In yet another embodiment, the nanomaterials can be a composite of nanotubes and nanowires. The composite mixture can include nanotubes of the same material or of different materials and nanowires of the same material or of different materials.

In a further embodiment, in addition to or alternative to the nanotubes and nanowires described above, the nanomaterials can include, but are not limited to, organic and inorganic, single or multi-walled nanotubes, nanowires, nanodots, quantum dots, nanorods, nanocrystals, nanotetrapods, nanotripods, nanobipods, nanoparticles, nanosaws, nanosprings, nanoribbons, any branched nanostructure, any mixture of these nanoshaped materials, and/or any other suitable nanomaterials or combination of nanomaterials.

These nanomaterials may be made of the following elements or compounds: gold (Au), silver (Ag), platinum (Pt), palladium (Pd), cobalt (Co), titanium (Ti), molybdenum (Mo), tungsten (W), manganese (Mn), chromium (Cr), iron (Fe), carbon (C), silicon (Si), germanium (Ge), boron (B), tin (Sn), silicon germanium (SiGe), silicon carbide (SiC), silicon tin (SiSn), germanium carbide (GeC), boron nitride (BN), indium phosphide (InP), indium nitride (InN), indium arsenide (InAs), indium antimonide (InSb), gallium nitride (GaN), gallium phosphide (GaP), gallium arsenide (GaAs), gallium antimonide (GaSb), aluminum nitride (AlN), aluminum phospide (AlP), aluminum arsenide (AlAs), aluminum antimonide (AlSb), cadmium oxide (CdO), cadmium sulfide (CdS), cadmium selenide (CdSe), cadmium telluride (CdTe), zinc oxide (ZnO), zinc sulfide (ZnS), zinc selenide (ZnSe), zinc telluride (ZnTe), magnesium oxide (MgO), magnesium sulfide (MgS), magnesium selenide (MgSe), magnesium telluride (MgTe), mercury oxide (HgO), mercury sulfide (HgS), mercury selenide (HgSe), mercury telluride (HgTe), lead oxide (PbO), lead sulfide (PbS), lead selenide (PbSe), lead telluride (PbTe), germanium sulfide (GeS), germanium selenide (GeSe), germanium telluride (GeTe), tin sulfide (SnS), tin selenide (SnSe), tin telluride (SnTe), indium oxide (InO), tin oxide (SnO), SiOₓ, germanium oxide (GeO), tungsten oxide (WO), titanium oxide (TiO), iron oxide (FeO), manganese oxide (MnO), cobalt oxide (CoO), nickel oxide (NiO), chromium oxide (CrO), vanadium oxide (VO), MSiO₄ (where M=Zn, Cr, Fe, Mn, Co, Ni, V, Ti), copper tin (CuSn), copper fluoride (CuF), copper chloride (CuCl), copper bromide (CuBr), copper iodide (CuI), silver fluoride (AgF), silver chloride (AgCl), silver bromide (AgBr), silver iodide (AgI), calcium cyanamide (CaCN₂), beryllium silicon nitride (BeSiN₂), zinc germanium diphosphide (ZnGeP₂), cadmium tin arsenide (CdSnAs₂), zinc tin antimonide (ZnSnSb₂), copper germanium phosphide (CuGe₂P₃), copper silicon phosphide (CuSi₂P₃), silicon nitride (Si₃N₄), germanium nitride (Ge₃N₄), aluminum oxide (Al₂O₃), aluminum oxycarbide (Al₂CO), or any combination thereof and any related alloys.

The nanomaterials may also comprise: a metal, such as gold (Au), nickel (Ni), palladium (Pd), iridium (Ir), cobalt (Co), chromium (Cr), aluminum (Al), or titanium (Ti); a metal alloy; a polymer; a conductive polymer; a ceramic material; or any combination thereof.

When a nanomaterial comprises a semiconductive material, the semiconductive material may further comprise a dopant. Dopants useful in the present invention include, but are not limited to: a p-type dopant, such as boron (B), aluminum (Al), indium (In), magnesium (Mg), zinc (Zn), cadmium (Cd), mercury (Hg), carbon (C), silicon (Si), an element from Group II of the periodic table, an element from Group III of the periodic table, or an element from Group IV of the periodic table; or an n-type dopant, such as silicon (Si), germanium (Ge), tin (Sn), sulfur (S), selenium (Se), tellurium (Te), phosphorus (P), arsenic (As), antimony (Sb), or an element from Group V of the periodic table.

In one embodiment, the dopant is a p-type dopant.

In another embodiment, the dopant is an n-type dopant.

When the nanostructure is a nanotube, nanowire, or nanoribbon, the nanotube, nanowire, or nanoribbon can comprise a conductive or semiconductive material, such as an organic polymer, pentacene, or a transition metal oxide.

In one embodiment, the composite mixture can include two or more distinct nanomaterials. For example, the composite mixture can include two different types of nanocrystal populations or a nanotube population and a nanoparticle population.

The nanomaterials can improve the carrier mobility and conductivity of the semiconductors. In the composite mixture, the nanomaterials may have an aligning influence on the rod-like organic semiconducting molecules in the polymers, as in the case of liquid crystals. In addition, the intrinsic electrical properties of the nanomaterials may also improve the overall electrical performance of the semiconductors.

The plurality of nanomaterials and organic semiconducting molecules can be aligned to improve carrier mobility and conductivity. For example, in a transistor, the nanomaterials are preferably aligned between its source electrode and drain electrode.

In one embodiment, prior to the deposition of the composite mixture by the ink-jet device, the surface of the substrate can be chemically treated. A chemical such as octadecyltrichlorosilane can be used to modify the surface of the substrate to facilitate alignment of the composite material. Alternatively, any other suitable chemical can be used to modify the surface of the substrate.

In another embodiment, the surface of the substrate can be mechanically rubbed in a preferential direction. Fine grooves can be created on the surface of the substrate in a direction along which the nanomaterials are intended to align, as occurs in liquid crystal cells.

In another embodiment, following the deposition of the composite mixture by the ink-jet device, but before the solvent has had time to fully evaporate, an electric field or alternating current can be applied across the electrodes of the semiconductor to align the nanomaterials in the desired direction.

In yet another embodiment, the alignment of the nanomaterials can be achieved during the growth phase of the nanomaterials. Aligned nanomaterials can be grown on a substrate prior to ink-jet deposition of the organic semiconducting material. This facilitates the fabrication of top-contact electrodes following ink-jet deposition.

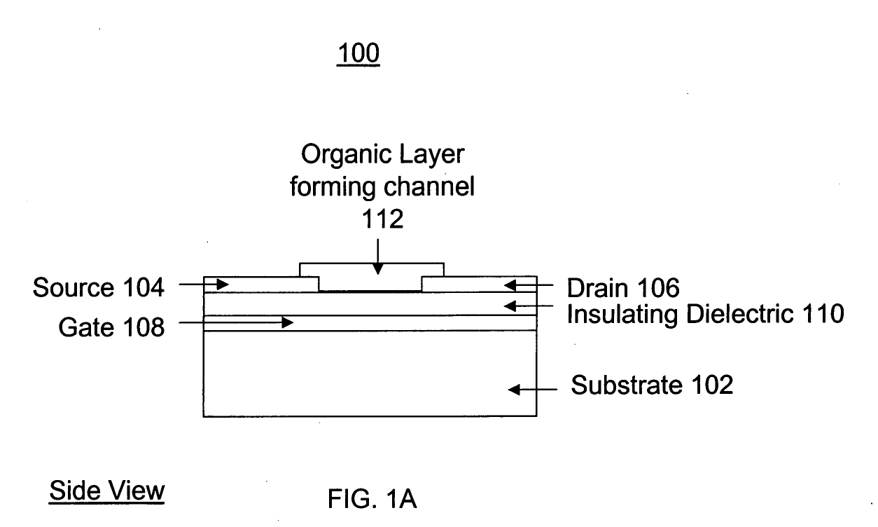

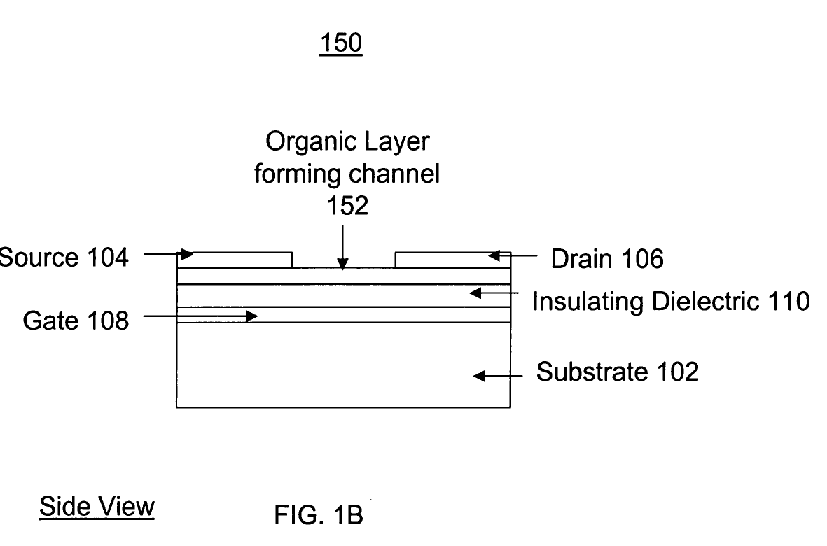

FIGS. 1A and 1B are diagrams of a cross-sectional side view of a semiconductor such as polymer transistors 100 and 150 in accordance with different embodiments of the invention. Transistors 100 and 150 can be organic thin film transistors. Transistors 100 and 150 each include a substrate 102, a source electrode 104, a drain electrode 106, a gate 108, and insulating dielectric 110. Substrate 102 can be glass, silicon, polyimide, ITO, or any other suitable organic or inorganic substrates.

Dielectric 110 provides insulation between source electrode 104 and gate 108, and between drain electrode 106 and gate 108. Although not shown, gate 108, source electrode 104, and drain electrode 106 can be connected to other transistors, voltage supplies, and/or any other suitable circuit components.

An organic layer forms a channel between source electrode 104 and drain electrode 106. The organic layer can be a composite layer of a polymer and nanomaterials. In one embodiment, as shown in FIG. 1A, an organic layer forming channel 112 is deposited over dielectric 110 in the space between source electrode 104 and drain electrode 106. In another embodiment, as shown in FIG. 1B, an organic layer forming channel 152 is deposited over the dielectric 110 and prior to the fabrication of electrodes 104 and 106. In both embodiments, when gate 108 reaches a particular voltage, transistors 100 and 150 turn “ON” such that a current is conducted between source electrode 104 and drain electrode 106 via channels 112 and 152, respectively.

FIGS. 1A and 1B illustrate two embodiments of the arrangement of substrate 102, source electrode 104, drain electrode 106, gate 108, dielectric 110, and organic layer forming channels 112 and 152 for clarity, though any other suitable arrangement may be used.

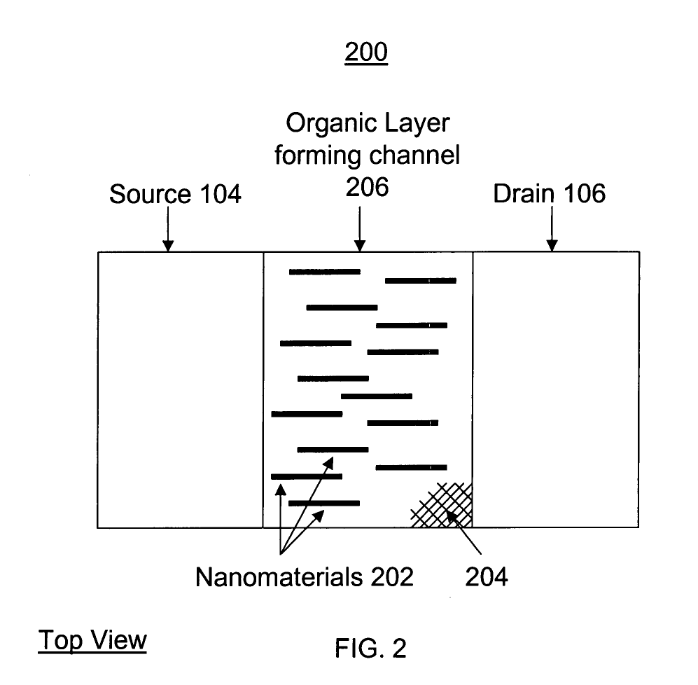

FIG. 2 is a diagram of a top view of a polymer transistor 200 in accordance with one embodiment of the invention. Transistor 200 includes source electrode 104 and drain electrode 106. In channel 206 (e.g., channel 112 or 152), composite mixture 204 is deposited over substrate 102. Mixture 204 includes a polymer, nanomaterials 202, and a solvent. The polymer can be P3HT, F8T2, PQT, or any other suitable polymer. The solvent can be IPA, DMF, toluene, chloroform, xylene, NMP, or any other suitable solvent. Once mixture 204 is deposited over dielectric 112, the solvent gradually evaporates, leaving a composite of the polymer and nanomaterials 202. Nanomaterials 202 can be aligned perpendicularly between source electrode 104 and drain electrode 106, and can be dispersed throughout channel 206 to improve carrier mobility and conductivity. Nanomaterials 202 can include, but are not limited to, organic and inorganic, single or multi-walled nanotubes, nanowires, nanodots, quantum dots, nanorods, nanocrystals, nanotetrapods, nanotripods, nanobipods, nanoparticles, nanosaws, nanosprings, nanoribbons, any branched nanostructure, any mixture of these nanoshaped materials, and/or any other suitable nanomaterials or combination of nanomaterials.

In another embodiment, an enhanced performance sensor device can also be realized using an ink-jet printed composite mixture that includes a semiconducting polymer having nanomaterials dispersed into an organic solvent. The sensor device can include any suitable insulating substrate and an ink-jet printed composite mixture deposited between and n-type and p-type electrodes. The electrical signal generated within the polymer composite upon detection is collected at the electrodes.

The nanomaterials in the composite mixture can improve the electrical performance of the organic semiconductors. The nanomaterials can act as enhancers of light, chemical or biological signal detection and conversion into electrical signals.

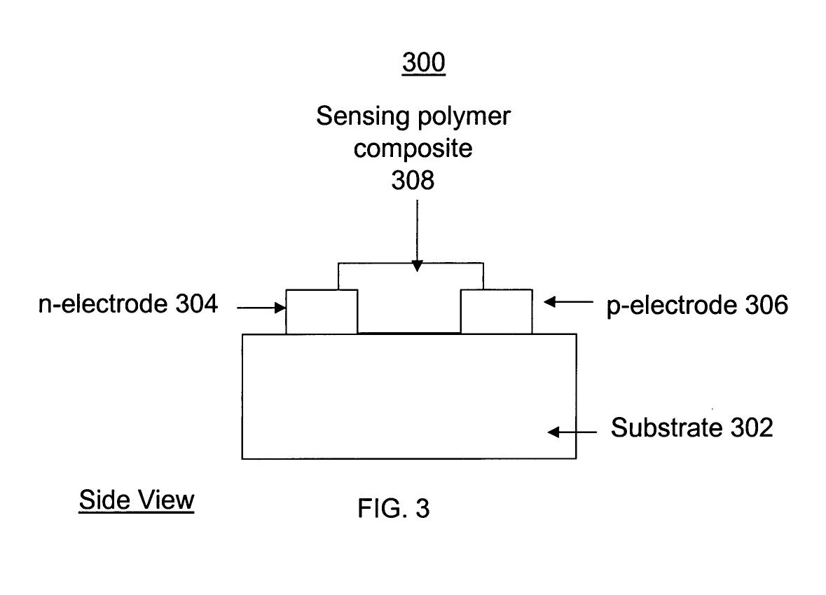

FIG. 3 is a diagram of a cross-sectional side view of a polymer sensor 300 in accordance with one embodiment of the invention. Polymer sensor 300 includes a substrate 302, an n-type electrode 304, a p-type electrode 306, and a sensing polymer composite 308. N-type electrode 304 and p-type electrode 306 are fabricated over substrate 302. Substrate 302 can be glass, silicon, polyimide, ITO, or any other suitable organic or inorganic substrates.

Between n-type electrode 304 and p-type electrode 308 is sensing polymer composite 308, which can be a polymer and nanomaterial composite layer deposited on the surface of substrate 302. When detection occurs within sensing polymer composite 308, a current is conducted between n-type electrode 304 and p-type electrode 306. FIG. 3 illustrates one embodiment of the arrangement of substrate 302, n-type electrode 304, p-type electrode 306 and sensing polymer composite 308 for clarity, though any other suitable arrangement may be used.

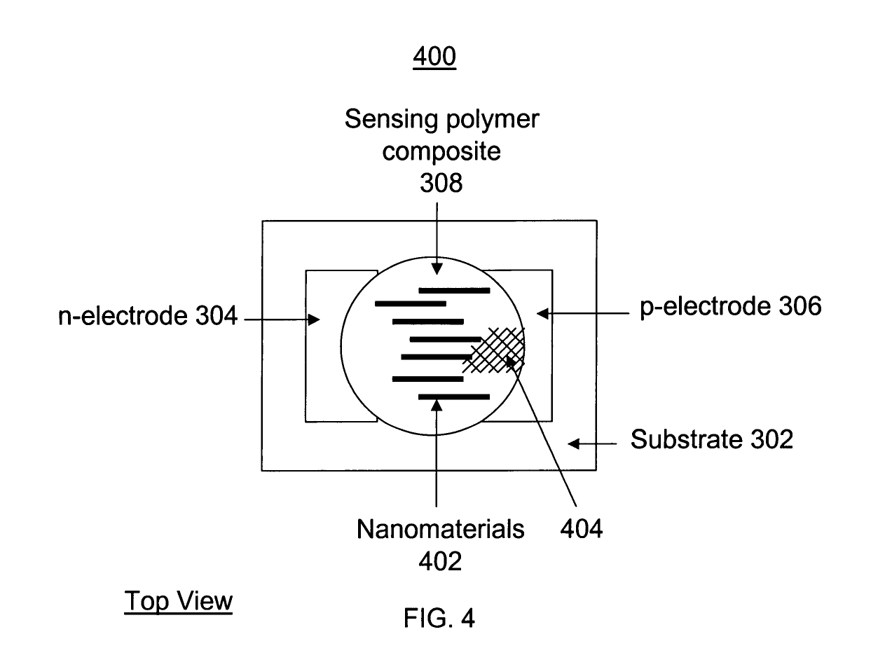

FIG. 4 is a diagram of a top view of a polymer sensor 400 in accordance with one embodiment of the invention. Sensor 400 includes substrate 302, n-type electrode 304, p-type electrode 306, sensing polymer composite 308. A composite mixture 404 is deposited over substrate 302 between n-type electrode 302 and p-type electrode 306. Mixture 404 includes a polymer, nanomaterials 402, and a solvent. The polymer can be P3HT, F8T2, PQT, pentacene, or any other suitable polymer. The solvent can be IPA, DMF, toluene, chloroform, xylene, NMP, or any other suitable solvent. Once mixture 404 is deposited over substrate 302, the solvent gradually evaporates, leaving a composite of the polymer and nanomaterials 402. Nanomaterials 402 can be aligned perpendicularly between n-type electrode 304 and p-type electrode 306, and can be dispersed in the area between electrodes 304 and 306 to improve sensitivity, responsitivity, and detection performance. Nanomaterials 402 can include, but are not limited to, organic and inorganic, single or multi-walled nanotubes, nanowires, nanodots, quantum dots, nanorods, nanocrystals, nanotetrapods, nanotripods, nanobipods, nanoparticles, nanosaws, nanosprings, nanoribbons, any branched nanostructure, any mixture of these nanoshaped materials, and/or any other suitable nanomaterials or combination of nanomaterials.

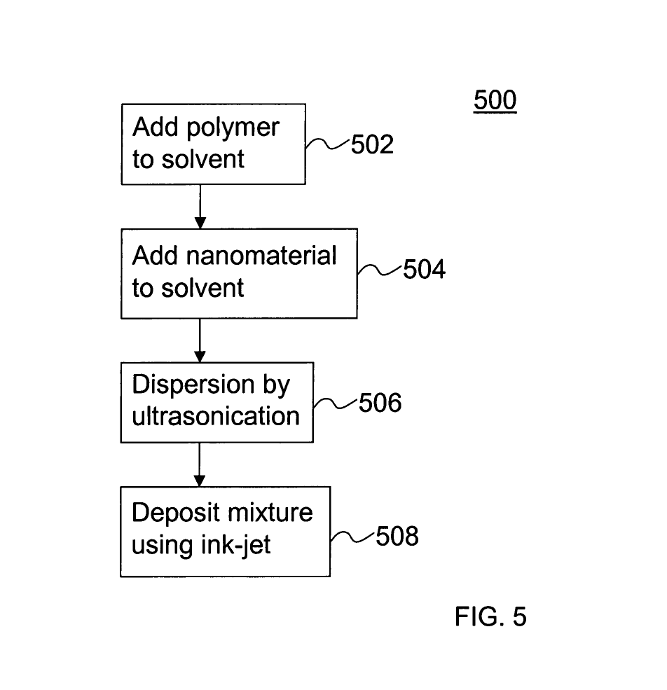

FIG. 5 is a flow diagram of a partial process 500 for ink-jet printing in accordance with one embodiment of the invention. At step 502, a polymer is added to an organic solvent. At step 504, nanomaterials 202 (e.g., organic and inorganic, single or multi-walled nanotubes, nanowires, nanodots, quantum dots, nanorods, nanocrystals, nanotetrapods, nanotripods, nanobipods, nanoparticles, nanosaws, nanosprings, nanoribbons, any branched nanostructure, any mixture of these nanoshaped materials, and/or any other suitable nanomaterials or combination of nanomaterials) are added to the same organic solvent. At step 506, a process such as ultrasonication is performed to disperse the polymer and nanomaterials in the solvent in order to achieve effective dispersion. At step 508, the resulting mixture 204 is deposited to on substrate 102 between the electrodes of the semiconducting device (e.g., between electrodes 104 and 106 of transistor 100/200) using an ink-jet device.

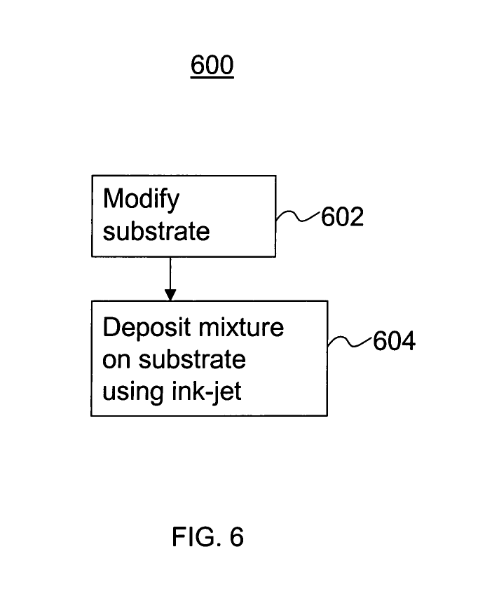

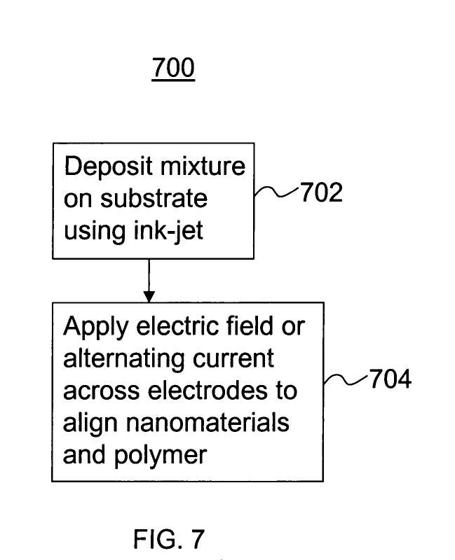

FIGS. 6 and 7 are flow diagrams of processes for aligning nanomaterials on substrate 102 of transistor 100/200 in accordance with different embodiments of the invention.

In FIG. 6, process 600 begins at step 602 where substrate 102 is treated. In one embodiment, the surface of substrate 102 can be modified using any suitable chemical such as, for example, octadecyltrichlorosilane to facilitate alignment of the composite material.

In another embodiment, the surface of substrate 102 can be mechanically rubbed in a preferential direction. Fine grooves can be created on the surface of the substrate in a direction along which the nanomaterials are intended to align.

At step 604, a composite mixture 204 of a polymer, nanomaterials 202, and solvent is deposited on substrate 102 using an ink-jet device. Based on the modified surface of substrate 102, the nanomaterials 202 are aligned between the electrodes of the semiconducting device (e.g., perpendicularly between electrodes 104 and 106 of transistor 100/200).

In FIG. 7, process 700 begins at step 702 where a composite mixture 204 of polymer, nanomaterials 202, and solvent is deposited on substrate 102 using an ink-jet device. At step 704, before the solvent fully evaporates, an electric field or an alternating current is applied across electrodes to align nanomaterials 202 perpendicularly between the electrodes of the semiconducting device (e.g., across electrodes 104 and 106 of transistor 100/200).

The use and alignment of nanomaterials in a composite material that is deposited onto a substrate of a transistor using an ink-jet device may advantageously improve the conductivity and thus performance of electronic circuits. The different embodiments of the invention can be applied to the field of polymer electronics as well as to the field of polymer optoelectronics.

In other embodiments, the processes describes in FIGS. 5-7 can be applied to the fabrication of sensing polymer composite 308 incorporated in sensor 300/400 as shown and described in connection with FIGS. 3 and 4.

The use and alignment of nanomaterials in a composite material that is deposited onto a substrate of a sensor using an ink-jet device may advantageously improve the sensitivity, responsitivity, and detection performance of the sensor.

According to one or more embodiments of the invention, the invention may advantageously improve the carrier mobility and conductivity of transistors, the carrier mobility and data processing speed in radio frequency identification (RFID) tags, the responsitivity of photodetectors, and the detection range of bio and chemical sensors produced using ink-jet manufacturing.

It is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of description and should not be regarded as limiting.

As such, those skilled in the art will appreciate that the conception, upon which this disclosure is based, may readily be utilized as a basis for the designing of other structures, methods, and systems for carrying out the purposes of the present invention. It is important, therefore, that the claims be regarded as including such equivalent constructions insofar as they do not depart from the spirit and scope of the present invention.

Although the present invention has been described and illustrated in the foregoing exemplary embodiments, it is understood that the present disclosure has been made only by way of example, and that numerous changes in the details of implementation of the invention may be made without departing from the spirit and scope of the invention, which is limited only by the claims which follow.

What is claimed is:

1. A method for improving the performance of an organic semiconductor device produced using an ink-jet, the method comprising:
dispersing a semiconducting polymer in an organic solvent;
dispersing a plurality of nanomaterials in the organic solvent; and
depositing a mixture comprising the organic solvent, the semiconducting polymer, and the plurality of nanomaterials from the ink-jet onto a substrate.

2. The method of claim 1 wherein the dispersing the semiconducting polymer and the plurality of nanomaterials comprises dispersing using ultrasonication.

3. The method of claim 1 further comprising aligning the plurality of nanomaterials and the organic molecules of the semiconducting polymer to improve carrier mobility and conductivity in a transistor.

4. The method of claim 1 further comprising aligning the plurality of nanomaterials and the organic molecules of the semiconducting polymer to improve sensitivity and responsitivity in a sensor.

5. The method of claim 1 further comprising aligning the plurality of nanomaterials in a preferential direction.

6. The method of claim 1 further comprises aligning the plurality of nanomaterials and the organic molecules of the semiconducting polymer, wherein the aligning comprises, prior to the depositing, at least one of:
chemically modifying the surface of the substrate; and
mechanically rubbing the surface of the substrate to create grooves in a direction along which the plurality of nanomaterials is intended to align.

7. The method of claim 1 further comprises aligning the plurality of nanomaterials and the organic molecules of the semiconducting polymer, wherein the aligning comprises, after the depositing, applying at least one of an electric field and an alternating current across the electrodes of the organic semiconductor device.

8. The method of claim 1 wherein the semiconducting polymer comprises at least one of poly(3-hexylthiophene), dioctylfluorene-bithiophene, poly(3,3′″-dialkyl-quaterthiophene), and pentacene.

9. The method of claim 1 wherein the organic solvent comprises at least one of isopropyl alcohol, dimethylformamide, toluene, chloroform, xylene, and N-methylpyrrolidone.

10. The method of claim 1 wherein the substrate comprises at least one of an organic substrate and an inorganic substrate, and wherein the substrate further comprises at least one of glass, silicon, polyimide, and indium tin oxide.

11. The method of claim 1 wherein the plurality of nanomaterials comprises at least one of organic nanomaterials, inorganic nanomaterials, and a mixture of organic and inorganic nanomaterials.

12. The method of claim 1 wherein the plurality of nanomaterials comprises at least one of single-walled nanotubes, multi-walled nanotubes, and a mixture of single and multi-walled nanotubes.

13. The method of claim 1 wherein the plurality of nanomaterials comprises at least one of nanotubes, nanostructures, and a mixture of nanotubes and nanostructures.

14. The method of claim 1 wherein the plurality of nanomaterials comprises at least one of organic and inorganic nanotubes, nanowires, nanodots, quantum dots, nanorods, nanocrystals, nanotetrapods, nanotripods, nanobipods, nanoparticles, nanosaws, nanosprings, nanoribbons, a branched nanostructure and a mixture of these nanoshaped materials, a nanosaw, a nanosping, a nanoribbon, a branched tetrapod, and a mixture of these nanoshaped materials.

15. The method of claim 1 wherein the plurality of nanomaterials comprises carbon nanotubes.

16. The method of claim 1 wherein the plurality of nanomaterials comprises silicon nanowires.

17. The method of claim 1 wherein the plurality of nanomaterials comprises a mixture of carbon nanotubes and silicon nanowires.

18. The method of claim 1 wherein the organic semiconductor device comprises at least one of a transistor, a sensor, a light emitting diode, and a photovoltaic device.
